(19) United States
(12) Patent Application Publication
(10) Pub. No.: US 2023/0238320 A1
(43) Pub. Date: Jul. 27, 2023

(54) High-Speed Signal Transition Across Thick Package Cores

(71) Applicant: Marvell Asia Pte Ltd, Singapore (SG)

(72) Inventors: Myles Kimmitt, Shrewsbury, MA (US); James R. Buszkiewicz, Westminster, MA (US)

(21) Appl. No.: 17/816,105

(22) Filed: Jul. 29, 2022

Related U.S. Application Data
(60) Provisional application No. 63/302,937, filed on Jan. 25, 2022.

(51) Int. Cl. H01L 23/528; H01L 23/64

(52) U.S. Cl. CPC H01L 23/528; H01L 23/64

(57) ABSTRACT

A tuning structure to mitigate a capacitive discontinuity in an integrated circuit (IC) package includes an electrical conductor having a first end, a second end, and a conductor body between the first end and the second end. The first end is electrically coupled to a signal via, and the second end electrically coupled to an IC package core via cap. The electrical conductor is disposed substantially coplanar with the core via cap, and the conductor body is disposed along an outer perimeter of the core via cap. The second end is coupled to the via cap at a contact location. The contact location is determined based on a measurement of a performance metric associated with the transmission path through the IC package core, the core via cap, the electrical conductor, and the signal via.

### RELATED APPLICATION

This application claims the benefit of U.S. Provisional Application No. 63/302,937, filed on Jan. 25, 2022. The entire teachings of the above application are incorporated herein by reference.

### BACKGROUND

An integrated circuit (IC) package encapsulates or holds (in the case of lidless packages) an IC die or dice to protect the IC die from environmental damage and to provide a robust interface for connection to other devices and systems (e.g., to a printed circuit board).

Advances in IC technology simultaneously require larger IC die size and higher speed input/output (I/O) signaling. The combination of these two requirements proves challenging for package design, particularly in signal transitions across the core layer. Larger IC dice require better co-planarity and higher package strength. This is achieved by using thicker package cores in the region of 1.2 mm or 1.4 mm. The goal of package design is to simultaneously meet the mechanical requirements and provide high quality signal interconnect from the die to the package system connect through the core at high speeds for external I/O. Such signals are often used for long reach links defined by Ethernet, Optical Internetworking Forum (OIF), PCI Express, and other standards. Signal quality lost in the package must be made up by the Silicon in such standards. This can lead to higher Silicon and power costs.

A set of build-up (BU) layers is fabricated on the top surface of the core and on the bottom surface of the core to make a complete package. The BU layers consist of layers of electrical conductors that are separated by layers of an electrically insulating dielectric material. The IC die mounts on the surface of the top set of BU layers. The bottom set of BU layers facilitate the interface to the other components in an electronics system. The core of the IC package gives the IC package its mechanical strength, so the core is substantially thicker than either the top or bottom set of BU layers. Structures that convey signals from one BU layer to another through the electrically insulating dielectric material, and/or through the core, are generally referred to as “electrical vias” or just “vias.” Vias are typically metallic cylinders that are electrically coupled to electrical conductors on the BU layers and/or to other electrical components. The vias that pass through the core (referred to herein as “core vias”) are terminated at each end by a “core via cap” (see, e.g., core via caps 108a, 108b in FIG. 1).

Because of the relatively large thickness of the core, propagation of high frequency signals through the core is problematic. This is partially due to the high capacitance between the differential core vias that pass through the core, the high dielectric constant of the core material, and a high capacitance associated with the via caps of the core layers and partially due to the high inductance of the via length. This produces a roll-off in signal transmission and rising reflections with higher frequency. A resonance also exists within the core via structure caused by the inherent inductance of the core vias and distributed capacitance of the core via, along with the capacitance of the core via caps. The resonance dropout frequency is roughly inversely proportional to the core thickness and becomes of interest when the resonance dropout frequency drops below 50 GHz with a core thickness around 1.2 mm.

Prior art solutions implement two differential core vias, surrounded by ground vias to carry common mode signal components. The structure is tuned by optimal spacing between the vias. FIG. 1 illustrates a typical core transition architecture of the prior art. Signal lines 102a, 102b in one of the layers in the top set of BU layers 104 connect to signal vias 106a, 106b. The signal vias 106a, 106b electrically couple the signal lines 102a, 102b to core via caps 108a, 108b, and the core via caps 108a, 108b are electrically coupled to core vias 110a, 110b. In FIG. 1 the core itself is not shown so that the core vias 110a, 110b can be seen. An opening 112 is excised from the BU layers that provides space to accommodate the signal vias 106a, 106b, the core via caps 108a,108b, and the core vias 110a, 110b themselves.

As shown in FIG. 2, the location of the capacitance is revealed by the electric field (E field) strength plots viewing the two core vias 110a, 110b in profile. Red regions represent high-magnitude E fields (i.e., more capacitance), and blue regions represent lower-magnitude E fields (i.e., less capacitance).

FIG. 3 illustrates the E field vectors around the core vias 110a, 110b. The E fields bend upward in the top half of the core vias 110a, 110b, and the E fields bend downwards the bottom half of the core vias 110a, 110b, mainly towards the surrounding ground planes, but also to the via caps 108a, 108b, 108c, 108d, thereby producing distributed capacitance to ground along the core vias 110a, 110b. It is the distributed capacitance from the core vias to the via caps that resonates with the intrinsic core via inductance to produce resonance transmission dropout.

### SUMMARY

The embodiments of the invention described herein are directed to a tuning structure configured to augment a transmission path through an integrated circuit (IC) package core. The tuned transmission path provides signal quality improvements that improve package performance, especially at higher transmission rates. Improved signal quality in the package potentially leads to a simpler Serialization/Deserialization (SerDes) with less equalization, which would have lower power.

Certain components of the transmission path through the IC package core contribute substantial capacitance to the transmission path, which interferes with signal transmission especially as the frequency of the signal increases. The tuning structure of the described embodiments may compensate for the excess capacitance of the IC core transmission path to mitigate the detrimental effects of the capacitance.

In one aspect, the invention may be a tuning structure to mitigate a capacitive discontinuity in an integrated circuit (IC) package, comprising an electrical conductor having a first end, a second end, and a conductor body between the first end and the second end. The first end may be electrically coupled to a signal via and the second end may be electrically coupled to an IC package core via cap. The electrical conductor may be disposed substantially coplanar with the core via cap, and the conductor body may be disposed along an outer perimeter of the core via cap.

The electrical conductor may extend along the outer perimeter of the core via cap through an angle θ measured from a first line extending from a center point of the core via cap to the signal via, to a second line extending from the center point of the core via cap to a contact location where the second end is electrically coupled to the core via cap. A transmission path may comprise the core via, the core via cap, the electrical conductor, and the signal via, and the contact location may be set by an adjustment of angle θ, based on a TDR measurement of the transmission path. The angle θ may be adjusted to reduce an impedance change produced by the TDR measurement. The angle θ may alternatively be adjusted to reduce a ripple magnitude of an insertion loss measurement. The angle θ may alternatively be adjusted to reduce a return loss magnitude in the return loss measurement. The angle θ may be between zero and 360°. The angle θ may be greater than 360°.

In another aspect, the invention may be a method of tuning an integrated circuit package transmission path, comprising coupling a first end of an electrical conductor to a signal via, and coupling a second end of the electrical conductor to an IC package core via cap. The electrical conductor may have a conductor body between the first end and the second end. The method may further comprise disposing the electrical conductor substantially coplanar with the core via cap, and disposing the conductor body along an outer perimeter of the core via cap.

The method may further comprise extending the electrical conductor along the outer perimeter of the core via cap through an angle θ measured from a first line extending from a center point of the core via cap to the signal via, to a second line extending from the center point of the core via cap to a contact location where the second end is electrically coupled to the core via cap.

The method may further comprise setting the contact location by an adjustment of angle θ, based on a TDR measurement of a transmission path that comprises the core via, the core via cap, the electrical conductor, and the signal via. The method may further comprise adjusting the angle θ to reduce an impedance change produced by the TDR measurement. The method may comprise moving the contact location by an adjustment of angle θ to reduce a ripple magnitude of an insertion loss measurement of the transmission path. The method may comprise moving the contact location by an adjustment of angle θ to reduce a return loss magnitude in a return loss measurement of the transmission path.

In another aspect, the invention may be a tuning structure, comprising a first via embedded in a core of an integrated circuit (IC) package, a via cap attached to an end of the first via, a second via electrically coupled to an IC die, an electrical conductor that electrically couples the via cap to the second via. The electrical conductor may extend around at least a portion of a perimeter of the via cap and electrically couple to the via cap at a contact location. A transmission path may comprise the first via, the via cap, the second via, and the electrical conductor. The contact location may be determined based on a measurement of a performance metric associated with the transmission path.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1 illustrates a typical core transition architecture of the prior art.

FIG. 2 shows the location of the capacitance of the core transition architecture shown in FIG. 1, based on electric field strength plots.

FIG. 3 illustrates the E field vectors around the core vias of the core transition architecture shown in FIG. 1.

FIGS. 4A and 4B illustrate example embodiments of the tuning elements according to the invention.

FIG. 5 illustrates an example embodiment of the tuning elements located at the bottom of the core.

FIGS. 6A, 6B, 7A, 7B, 8A, and 8B illustrate examples comparing metrics of a baseline core transmission path and transmission path with tuning conductors according to the described embodiments.

### DETAILED DESCRIPTION

A description of example embodiments follows.

The described embodiments are directed to a tuning element associated with a core via of an integrated circuit (IC) package. The core via is part of a transmission path from the IC die within the IC package to external interface of the IC package (e.g., a ball contact of a ball grid array (BGA)). The structure of the core via and the associated core via cap produces a capacitive discontinuity that adversely affects signal transmission through the transmission path, particularly at higher signal frequencies. The inductance of the tuning element interacts with the capacitance of the core via and core via cap to mitigate the adverse effect to signal propagation. The tuning elements are implemented above and below the core vias, and are electrically integrated directly with the core via caps. The inductance of the tuning element is dependent on several factors as is known in the art, for example tuning element length, thickness, shape, physical configuration, orientation, among others.

The tuning elements significantly improve insertion loss and reflections at high frequencies. The tuning elements also push the transition resonance above 50 GHz for 1.2 mm cores. The shape of the tuning elements above the core is different from the tuning elements below the core, driven by connectivity and the need to be able to reverse signal polarity easily. Polarity reversal is achieved by mirror imaging the bottom core structure about the long axis. The tuning elements are also designed to fit into roughly the same area to keep the same overall signal density within the package.

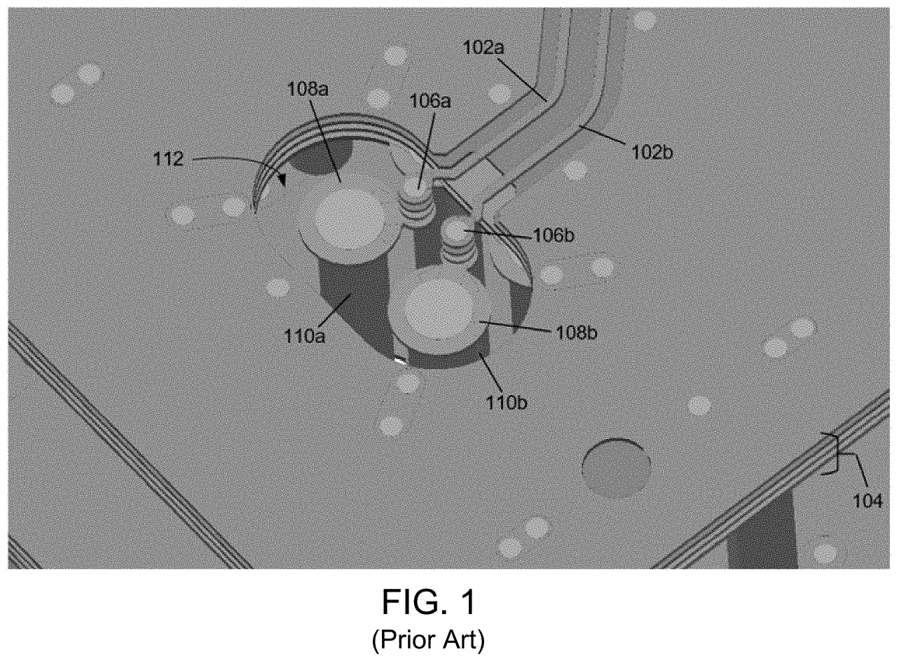

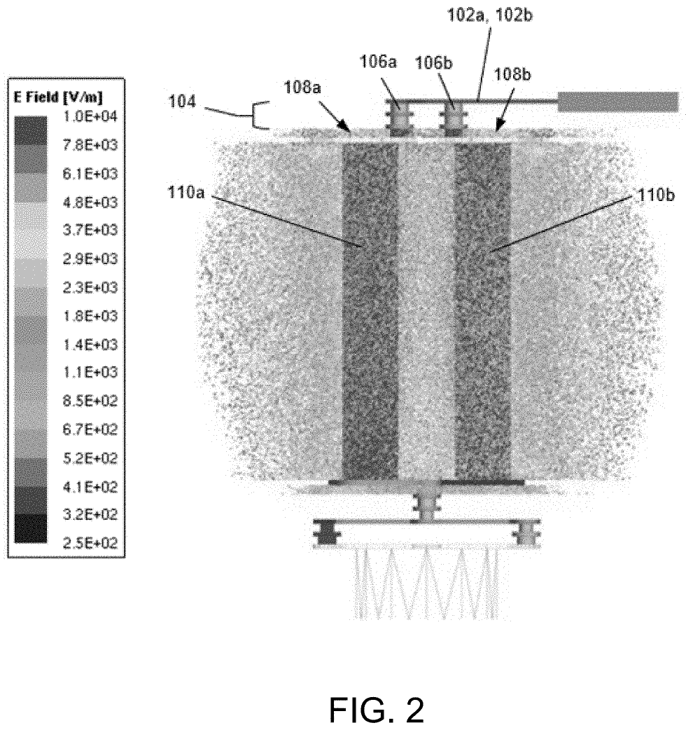

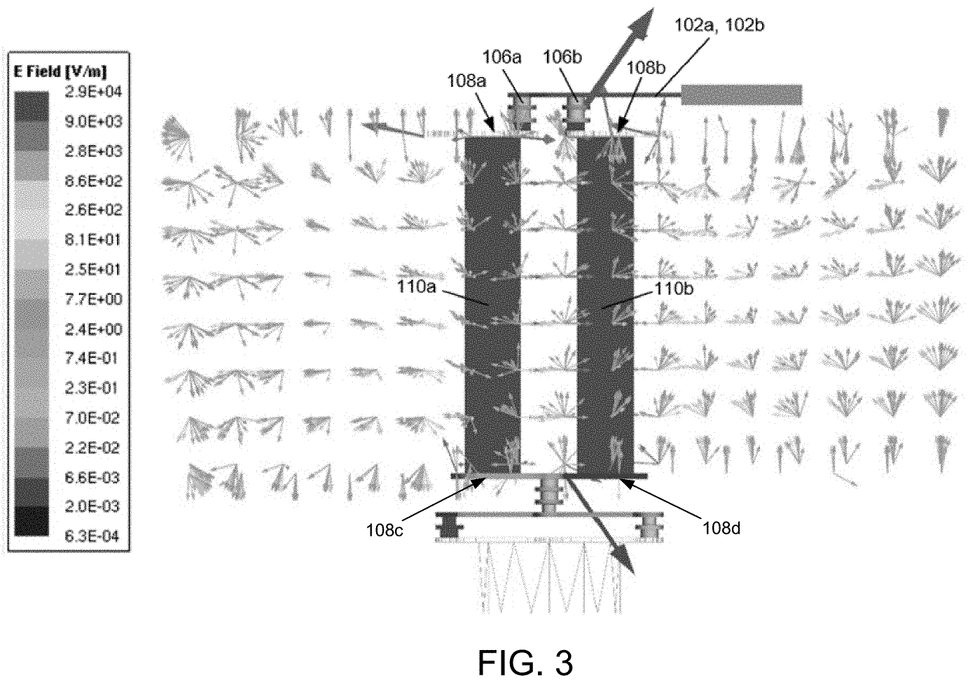

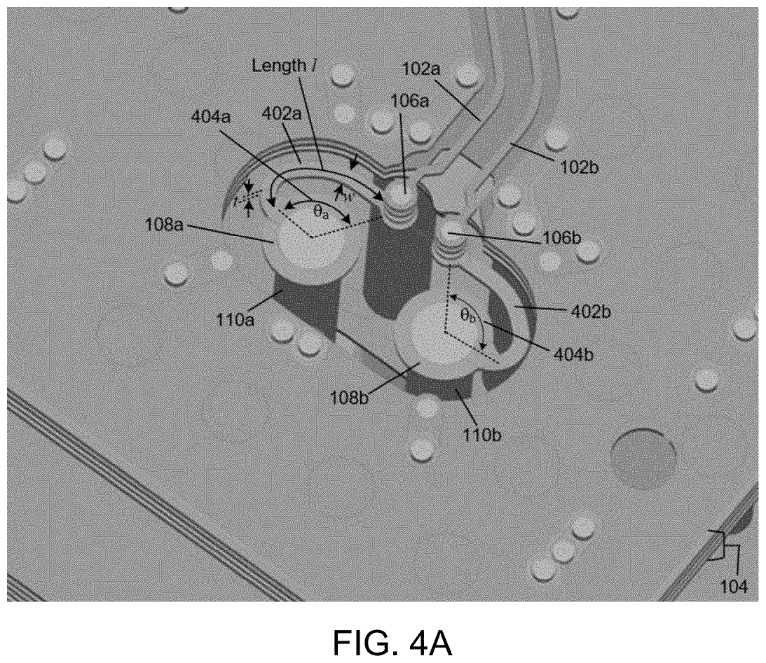

FIG. 4A illustrates an example embodiment of the tuning elements according to the invention. FIG. 4A shows the tuning elements at the core via caps at the top of the core (i.e., at the bottom of the BU layers near the IC die). Referring to FIG. 1, it was shown that in the prior art, the signal via 106a electrically couples directly to the core via cap 108a, i.e., without a substantial coupling conductor between the signal via 106a and the core via cap 108a. By contrast, the example embodiment shown in FIG. 4A further comprises tuning conductor 402a, configured such that signal via 106a is electrically coupled to core via cap 108a through 402a. Similarly, tuning conductor 402b electrically couples signal via 106b to core via cap 108b.

In this example embodiment, the tuning conductor 402a extends the propagation path of the signal from the signal via 106a to the core via cap 108a, along the perimeter of the core via cap 108a, through an angle of θₐ, which results in the tuning conductor 402a having a length l. Similarly, the tuning conductor 402b extends the propagation path of the signal from the signal via 106b to the core via cap 108b, along the perimeter of the core via cap 108b, through an angle of Ob, which results in the tuning conductor 402a having a length l. In the example embodiment, the tuning conductors 402a, 402b have a width w and a thickness t, as shown in FIG. 4A. The particular values of l, w, and t are dependent on the capacitance values exhibited by the core vias 110a, 110b, and the core via caps 108a, 108b. In the example embodiment, the angles θₐ and θ_{b} are substantially equal, so lengths of the tuning conductors 402a, 402b are substantially the same. In other embodiments, however, the angles θₐ and θ_{b} may be different. Further, the angle θₐ (or θ_{b}) may be greater than 360°, so that the tuning conductor 402a (or 402b) forms a spiral around the core via 110a that completely encircles the core via 110a with more than one complete rotation around the perimeter of the core via 110a, as depicted in the example embodiment of FIG. 4B.

In the example embodiment shown in FIG. 4A, the tuning conductors 402a, 402b are depicted as being substantially within the same plane as the core via caps 108a, 108b. Doing so ensures that the tuning conductors 402a, 402b reside completely within the opening 112, such that the overall signal density, as compared to the IC package design without the tuning conductors, remains substantially the same. Other embodiments, however, may utilize additional space to accomplish the required compensation effects, which may involve a trade-off with respect to available signal density. Some embodiments may increase the size of the opening 112 to accommodate larger or different shaped tuning conductors 402a, 402b. Some embodiments may incorporate tuning conductors that are disposed outside of the plane of the core via caps 108a, 108b, instead of (or in addition to) occupying space within the plane of the core via caps 108a, 108b.

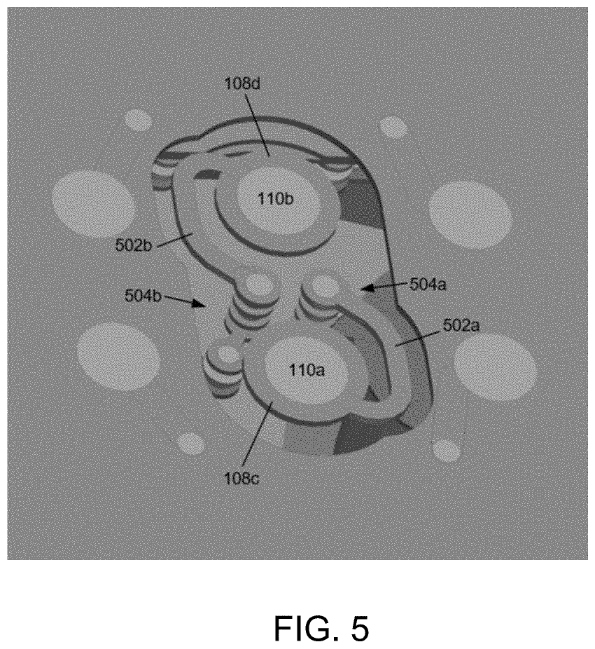

FIG. 5 illustrates an example embodiment of the tuning elements 502a, 502b located at the bottom of the core (i.e., at the BU layers at the bottom of the core, nearer to the BGA contacts), connected between the bottom caps 108c, 108d of core vias 110a, 110b, and the connection to the BGA through vias 504a, 504b, respectively. As a comparison of FIGS. 4A and 5 shows, the shape of the tuning elements 502a, 502b is different above and below the core. The differences are driven by (i) connectivity and (ii) the need to be able to reverse signal polarity easily. Polarity reversal is achieved by mirror imaging the bottom core structure about the long axis.

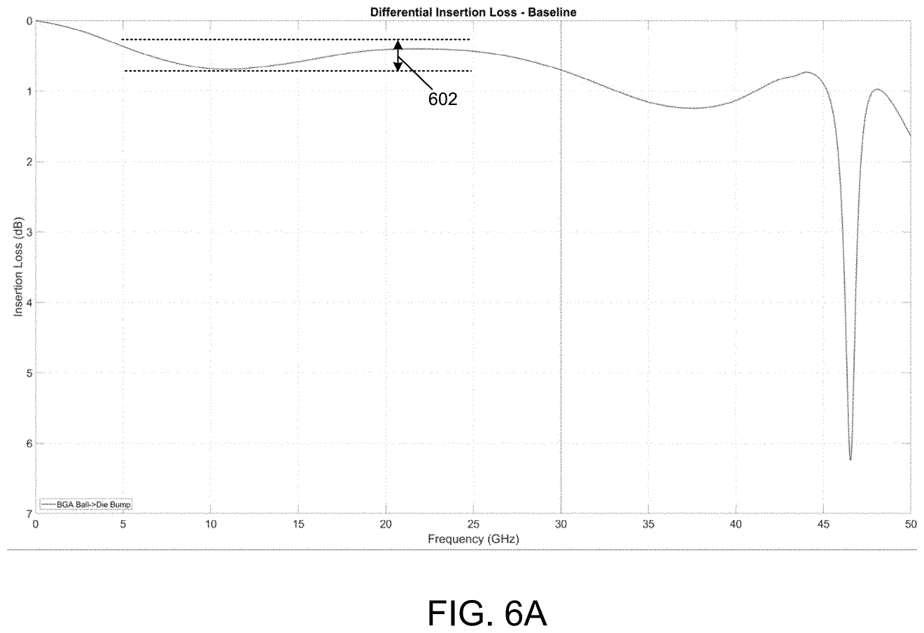

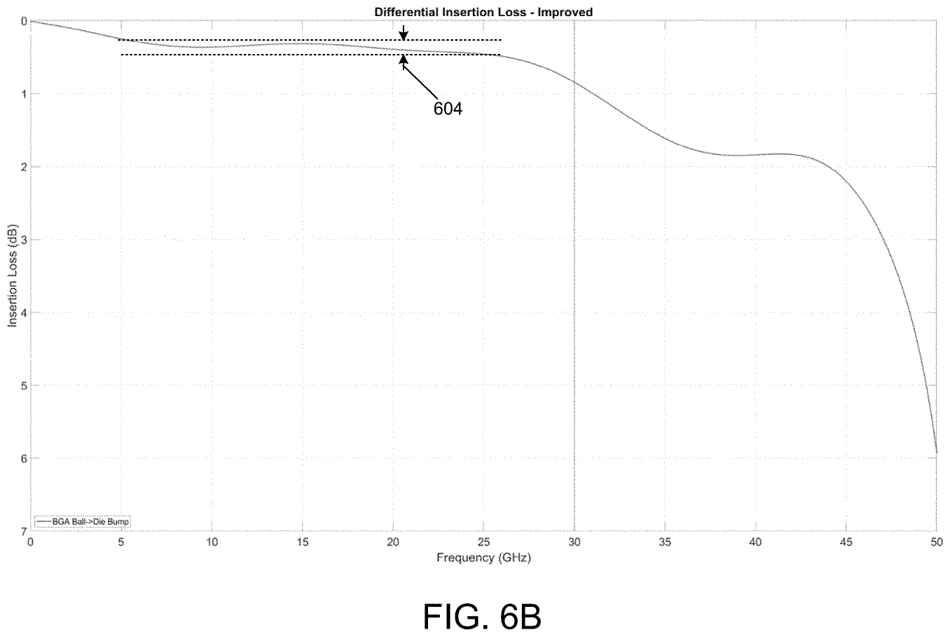

Three performance metrics, Insertion Loss, Return Loss, and Time Domain Reflectometry (TDR) may be used to show improvement over the baseline design. FIGS. 6A, 6B, 7A, 7B, 8A, and 8B illustrate examples comparing performance metrics of a baseline core transmission path without tuning conductors and transmission path with tuning conductors according to the described embodiments. FIGS. 6A, 6B, 7A, 7B, 8A, and 8B were all generated same the same tool flow to remove any tool bias. A complete transition from ball grid array (BGA) ball to the routing layer above the core is considered in these figures. The BGA is 1 mm pitch and 0.65 mm ball size for these figures. Although FIGS. 6A, 6B, 7A, 7B, 8A, and 8B show results up to 50 GHz, the analysis described herein only concerns signal frequencies up to 30 GHz.

FIGS. 6A and 6B illustrate differential insertion loss for a baseline transmission path through an IC core and a transmission path according to the described embodiments. FIG. 6A illustrates a ripple in the insertion loss ripple 602 of approximately 0.6 dB for the baseline transmission path, while the described embodiment shows an improved insertion loss ripple 604 of about 0.2 dB. There is also less average insertion loss up to 30 GHz for the described embodiment.

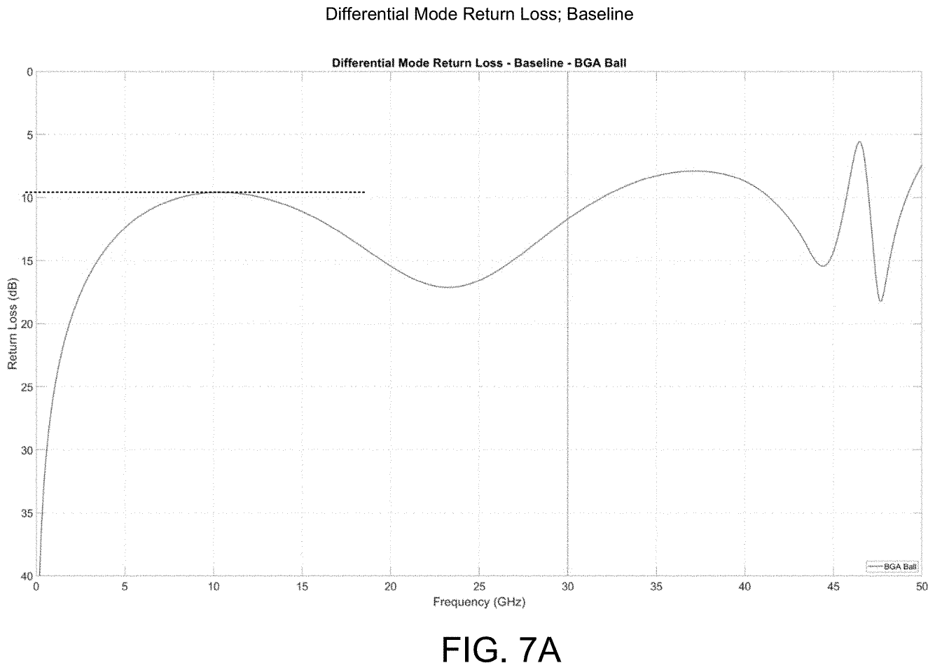

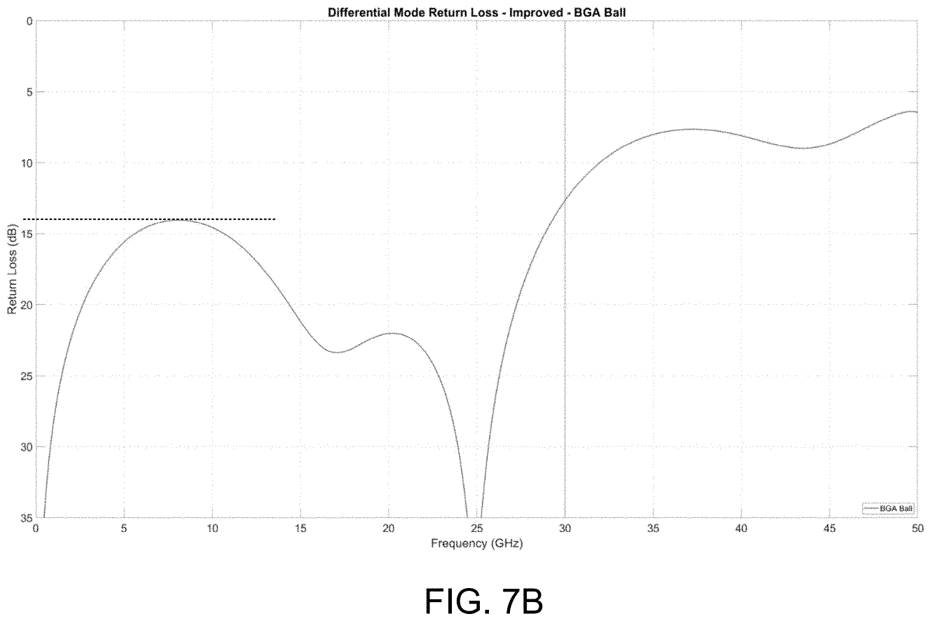

FIGS. 7A and 7B show differential return loss for the baseline transmission path and the transmission path according to the described embodiments. A comparison of FIG. 7A to FIG. 7B shows about a 5 dB improvement in the maximum return loss.

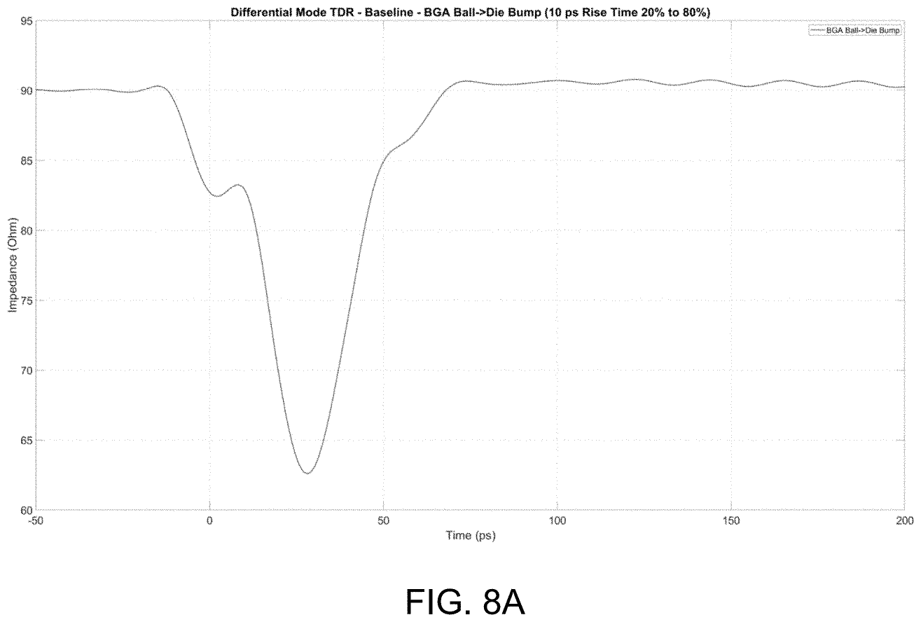

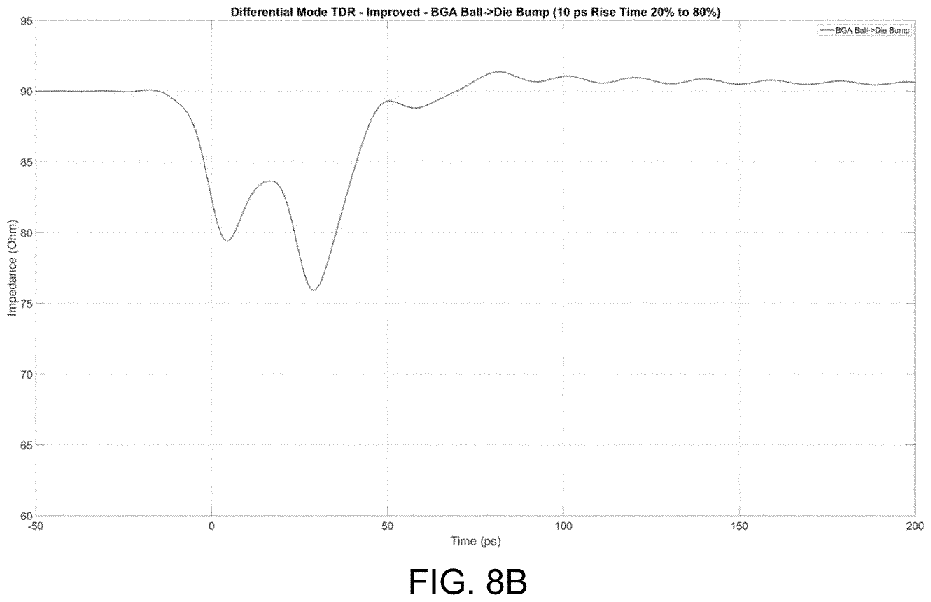

FIGS. 8A and 8B illustrate differential mode Time Domain Reflectometry (TDR) results for the baseline transmission path and the transmission path according to the described embodiments. FIG. 8A shows a drop of approximately 27 ohms at approximately 25 pS. Such a drop indicates a capacitive discontinuity due to the core via cap in the transmission path. FIG. 8B shows a drop of only about 14 ohms, demonstrating an improvement afforded by the tuning conductors of the described embodiments.

While example embodiments have been particularly shown and described, it will be understood by those skilled in the art that various changes in form and details may be made therein without departing from the scope of the embodiments encompassed by the appended claims.

What is claimed is:

1. A tuning structure to reduce a capacitive discontinuity in an integrated circuit (IC) package, comprising:
an electrical conductor having a first end, a second end, and a conductor body between the first end and the second end, the first end electrically coupled to a signal via and the second end electrically coupled to an IC package core via cap;
the electrical conductor disposed substantially coplanar with the core via cap, and the conductor body disposed along an outer perimeter of the core via cap.

2. The tuning structure of claim 1, wherein the electrical conductor extends along the outer perimeter of the core via cap through an angle θ measured from a first line extending from a center point of the core via cap to the signal via, to a second line extending from the center point of the core via cap to a contact location where the second end is electrically coupled to the core via cap.

3. The tuning structure of claim 2, wherein a transmission path comprises the core via, the core via cap, the electrical conductor, and the signal via, and wherein the contact location is set by an adjustment of angle θ, based on a TDR measurement of the transmission path.

4. The tuning structure of claim 3, wherein the angle θ is adjusted to reduce an impedance change produced by the TDR measurement.

5. The tuning structure of claim 2, wherein a transmission path comprises the core via, the core via cap, the electrical conductor, and the signal via, and wherein the contact location is moved by an adjustment of angle θ, based on an insertion loss measurement of the transmission path.

6. The tuning structure of claim 5, wherein the angle θ is adjusted to reduce a ripple magnitude of the insertion loss measurement.

7. The tuning structure of claim 2, wherein a transmission path comprises the core via, the core via cap, the electrical conductor, and the signal via, and wherein the contact location is moved by an adjustment of angle θ, based on a return loss measurement of the transmission path.

8. The tuning structure of claim 7, wherein the angle θ is adjusted to reduce a return loss magnitude in the return loss measurement.

9. The tuning structure of claim 2, wherein the angle θ is between zero and 360°.

10. The tuning structure of claim 2, wherein the angle θ is greater than 360°.

11. A method of tuning an integrated circuit package transmission path, comprising:
coupling a first end of an electrical conductor to a signal via;
coupling a second end of the electrical conductor to an IC package core via cap, the electrical conductor having a conductor body between the first end and the second end;
disposing the electrical conductor substantially coplanar with the core via cap, and
disposing the conductor body along an outer perimeter of the core via cap.

12. The method of claim 11, further comprising extending the electrical conductor along the outer perimeter of the core via cap through an angle θ measured from a first line extending from a center point of the core via cap to the signal via, to a second line extending from the center point of the core via cap to a contact location where the second end is electrically coupled to the core via cap.

13. The method of claim 12, further comprising moving the contact location by an adjustment of angle θ, based on a TDR measurement of a transmission path, wherein the transmission path comprises the core via, the core via cap, the electrical conductor, and the signal via.

14. The method of claim 13, further comprising adjusting the angle θ to reduce an impedance change produced by the TDR measurement.

15. The method of claim 12, further comprising moving the contact location by an adjustment of angle θ, based on an insertion loss measurement of a transmission path, wherein the transmission path comprises the core via, the core via cap, the electrical conductor, and the signal via.

16. The method of claim 15, further comprising adjusting the angle θ to reduce a ripple magnitude of the insertion loss measurement.

17. The method of claim 12, further comprising moving the contact location by an adjustment of angle θ, based on a return loss measurement of a transmission path, wherein the transmission path comprises the core via, the core via cap, the electrical conductor, and the signal via.

18. The method of claim 17, further comprising adjusting the angle θ to reduce a return loss magnitude in the return loss measurement.

19. A tuning structure, comprising:
a first via embedded in a core of an integrated circuit (IC) package;
a via cap attached to an end of the first via;
a second via electrically coupled to an IC die;
an electrical conductor that electrically couples the via cap to the second via, the electrical conductor extends around at least a portion of a perimeter of the via cap and electrically couples to the via cap at a contact location.

20. The tuning structure of claim 19, wherein a transmission path comprises the first via, the via cap, the second via, and the electrical conductor, and wherein the contact location is determined based on a measurement of a performance metric associated with the transmission path.
